(19) United States
(12) Patent Application Publication
(10) Pub. No.: US 2024/0222933 A1
(43) Pub. Date: Jul. 4, 2024

(54) SUB-RATE ASYMMETRIC FFE GENERATION FOR OPTICAL TRANSMITTER

(71) Applicant: National Tsing Hua University, Hsinchu City (TW)

(72) Inventors: Pen-Jui Peng, Hsinchu City (TW); Po-Lin Lee, Hsinchu City (TW)

(73) Assignee: National Tsing Hua University, Hsinchu City (TW)

(21) Appl. No.: 18/180,865

(22) Filed: Mar. 9, 2023

(30) Foreign Application Priority Data
Jan. 3, 2023 (TW) 112100054

(51) Int. Cl. H01S 5/068; H01S 5/183; H03K 5/1534

(52) U.S. Cl. CPC H01S 5/06808; H01S 5/183; H03K 5/1534

(57) ABSTRACT

An edge detector applied to a vertical-cavity surface-emitting laser is provided. The edge detector includes an alignment circuit, a rising-edge detecting circuit and a falling-edge detecting circuit. The alignment circuit is configured to receive and align multiple sets of differential input data and output multiple sets of differential output data corresponding to the multiple sets of differential input data. The multiple sets of differential output data include a set of delayed differential output data. The rising-edge detecting circuit is coupled to the alignment circuit. The rising-edge detecting circuit is configured to detect rising edges of the multiple sets of differential output data and output multiple sets of corresponding differential rising data. The falling-edge detecting circuit is coupled to the alignment circuit. The falling-edge detecting circuit is configured to detect falling edges of the multiple sets of differential output data and output multiple sets of corresponding differential falling data.

### CROSS-REFERENCE TO RELATED APPLICATION

This application claims the priority benefit of Taiwan application no. 112100054, filed on Jan. 3, 2023. The entirety of the above-mentioned patent application is hereby incorporated by reference herein and made a part of this specification.

### BACKGROUND

### Technical Field

The disclosure relates to an edge detector. Particularly, the disclosure relates to an edge detector applied to a vertical-cavity surface-emitting laser (VCSEL).

### Description of Related Art

A vertical-cavity surface-emitting laser (VCSEL) is one of the popular laser application device at present, which not only has low costs and a high transmission rate, but may also be widely applied to transmission systems, sensors, and data centers. However, due to nonlinear effects of the VCSEL, a transfer function of the device may change as a driving current is reduced. In addition, rising pulses and falling pulses output by the VCSEL are also asymmetric, so a conventional feed-forward equalizer (FFE) cannot compensate for the nonlinear characteristics of the VCSEL.

To address to asymmetry of the above output pulses, conventionally, data transitions are detected through an asymmetric FFE, and corresponding rising and falling pulses are generated for a current-mode driver of the VCSEL to improve outputs thereof. However, since the transmission rate is increased on a daily basis, the bandwidth and clock frequency of an edge detector may inevitably encounter bottlenecks. For example, some full-rate edge detector are used conventionally, but the bandwidth of a logic gate in this design may be limited by process limitations when the transmission rate of the VCSEL is increased.

As a result, it is necessary to design an edge detector to address the above issues.

### SUMMARY

The disclosure provides an edge detector applied to a vertical-cavity surface-emitting laser, which may reduce burden on a logic gate and improve an operating speed of a VCSEL.

In the disclosure, an edge detector is applied to a vertical-cavity surface-emitting laser. The edge detector includes an alignment circuit, a rising-edge detecting circuit, and a falling-edge detecting circuit. The alignment circuit is configured to receive a plurality of sets of differential input data, and align the differential input data to output a plurality of sets of corresponding differential output data. The differential output data include a set of delayed differential output data. The rising-edge detecting circuit is coupled to the alignment circuit. The rising-edge detecting circuit is configured to detect rising edges of the differential output data to output a plurality of sets of corresponding differential rising data. The falling-edge detecting circuit is coupled to the alignment circuit. The falling-edge detecting circuit is configured to detect falling edges of the differential output data to output a plurality of sets of corresponding differential falling data. The plurality of sets of differential rising data and the plurality of sets of differential falling data that are output are input to a feed-forward equalizer at a next level to shift data phases. Moreover, the differential rising data and the differential falling data are respectively synthesized into full-rate rising pulses and falling pulses through a multiplexer circuit at a last level.

In an embodiment of the disclosure, the alignment circuit receives N sets of differential input data and outputs N+1 sets of differential output data, and the edge detector is a one-Nth-rate edge detector.

In an embodiment of the disclosure, the alignment circuit receives four sets of differential input data, the edge detector is a quarter-rate edge detector.

In an embodiment of the disclosure, the rising-edge detecting circuit includes a plurality of first type logic gates and a plurality of second type logic gates. Each of the first type logic gates and the second type logic gates receives differential output data of the same timing.

In an embodiment of the disclosure, each of the first type logic gates and the second type logic gates receives in-phase differential output data of different data sequences.

In an embodiment of the disclosure, a first logic gate among the first type logic gates receives first differential data in the set of delayed differential output data, and a second logic gate among the second type logic gates receives the first differential data in the set of delayed differential output data.

In an embodiment of the disclosure, the falling-edge detecting circuit includes a plurality of third type logic gates and a plurality of fourth type logic gates. Each of the third type logic gates and the fourth type logic gates receives differential output data of the same timing. The first type logic gates and the third type logic gates are logic gates of the same type, and the second type logic gates and the fourth type logic gates are logic gates of the same type.

In an embodiment of the disclosure, each of the third type logic gates and the fourth type logic gates receives in-phase differential output data of different data sequences.

In an embodiment of the disclosure, a third logic gate among the third type logic gates receives second differential data in the set of delayed differential output data, and a fourth logic gate among the third type logic gates receives the second differential data in the set of delayed differential output data.

In an embodiment of the disclosure, the differential rising data and the differential falling data form a full-rate pulse sequence through a multiplexer circuit.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a block diagram showing an edge detector applied to a vertical-cavity surface-emitting laser according to an embodiment of the disclosure.

FIG. 2 is a circuit diagram showing an edge detector according to an embodiment of the disclosure.

FIG. 3 is a schematic diagram showing a multiplexer circuit according to an embodiment of the disclosure.

FIG. 4 is a schematic diagram showing full-rate pulse sequences according to an embodiment of the disclosure.

### DESCRIPTION OF THE EMBODIMENTS

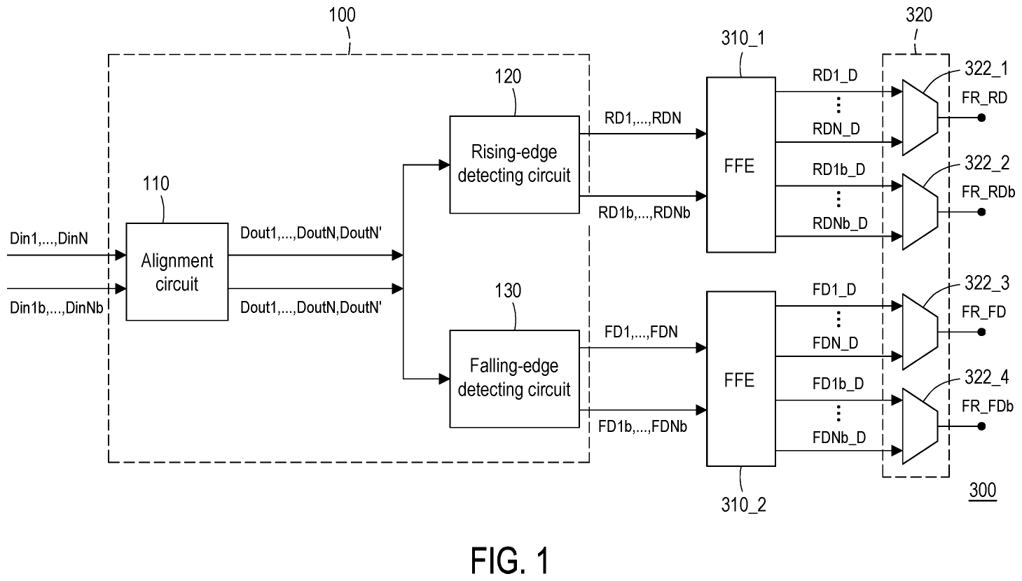

FIG. 1 is a block diagram showing an edge detector applied to a vertical-cavity surface-emitting laser according to an embodiment of the disclosure. With reference to FIG. 1, in this embodiment, a vertical-cavity surface-emitting laser 300 includes an edge detector 100, feed-forward equalizer (FFE) circuits 310_1 and 310_2, and a multiplexer circuit 320. The edge detector 100 includes an alignment circuit 110, a rising-edge detecting circuit 120, and a falling-edge detecting circuit 130. The rising-edge detecting circuit 120 is coupled to the alignment circuit 110. The falling-edge detecting circuit 130 is coupled to the alignment circuit 110.

Specifically, the alignment circuit 110 is configured to receive a plurality of sets of differential input data Din1, . . . , DinN, Din1b, . . . , and DinNb, and align the differential input data Din1, . . . , DinN. Din1b, . . . , and DinNb to output a plurality of sets of corresponding differential output data Dout1, . . . , DoutN, and DoutN′. The differential output data Dout1, . . . , DoutN, and DoutN′ include a set of delayed differential output data DoutN′. Din1, . . . , and DinN represent N pieces of data. Din1b, . . . , and DinNb represent N pieces of data, and Dout1, . . . , DoutN, and DoutN′ represent N+1 pieces of data, where N is a power of 2.

The rising-edge detecting circuit 120 is configured to detect rising edges of the differential output data Dout1, . . . , DoutN, and DoutN′ of the same timing to output a plurality of sets of corresponding differential rising data RD1, . . . , RDN, RD1b, . . . , and RDNb. The falling-edge detecting circuit 130 is configured to detect falling edges of the differential output data Dout1, . . . , DoutN, and DoutN′ of the same timing to output a plurality of sets of corresponding differential falling data FD1, . . . , FDN, FD1b, . . . , and FDNb.

In this embodiment, for example, the alignment circuit 110 receives N sets of differential input data and outputs N+1 sets of differential output data. Moreover, the edge detector 100 is a one-Nth-rate edge detector, where N is a power of 2. For example, in an embodiment, the edge detector 100 is a half-rate edge detector. Alternatively, in an embodiment, the edge detector 100 is a quarter-rate edge detector.

The differential rising data RD1, . . . , RDN. RD1b, . . . , and RDNb and the differential falling data FD1, . . . , FDN, FD1b, . . . , and FDNb are input to the corresponding FFE circuits 310_1 and 310_2 at the next level to shift data phases. For example, the FFE circuit 310_1 receive the differential rising data RD1, . . . , RDN, RD1b, . . . , and RDNb to shift data phases, and respectively output phase-shifted differential rising data RD1_D, . . . , and RDN_D and phase-shifted differential rising data RD1b_D, . . . , and RDNb_D. The FFE circuit 310_2 receive the differential falling data FD1, . . . , FDN. FD1b, . . . , and FDNb to shift data phases, and respectively output phase-shifted differential falling data FD1_D, . . . , and FDN_D and phase-shifted differential falling data FD1b_D, . . . , and FDNb_D.

Then, the differential rising data and the differential falling data are respectively synthesized into full-rate rising pulses and falling pulses through the multiplexer circuit 320 at the last level. Specifically, the multiplexer circuit 320 includes a plurality of N:1 multiplexers 322_1, 322_2, 322_3, and 322_4. The multiplexer 322_1 receives the differential rising data RD1_D, . . . , and RDN_D and synthesizes them into a full-rate rising pulse FR_RD; the multiplexer 322_2 receives the differential rising data RD1b_D, . . . , and RDNb_D and synthesizes them into a full-rate rising pulse FR_RDb. The multiplexer 322_3 receives the differential falling data FD1_D, . . . , and FDN_D and synthesizes them into a full-rate falling pulse FR_FD; the multiplexer 322_4 receives the differential falling data FD1b_D, . . . , and FDNb_D and synthesizes them into a full-rate falling pulse FR_FDb.

An edge detector of an embodiment of the disclosure will be described below taking a quarter-rate edge detector as an example, which is not intended to limit the disclosure.

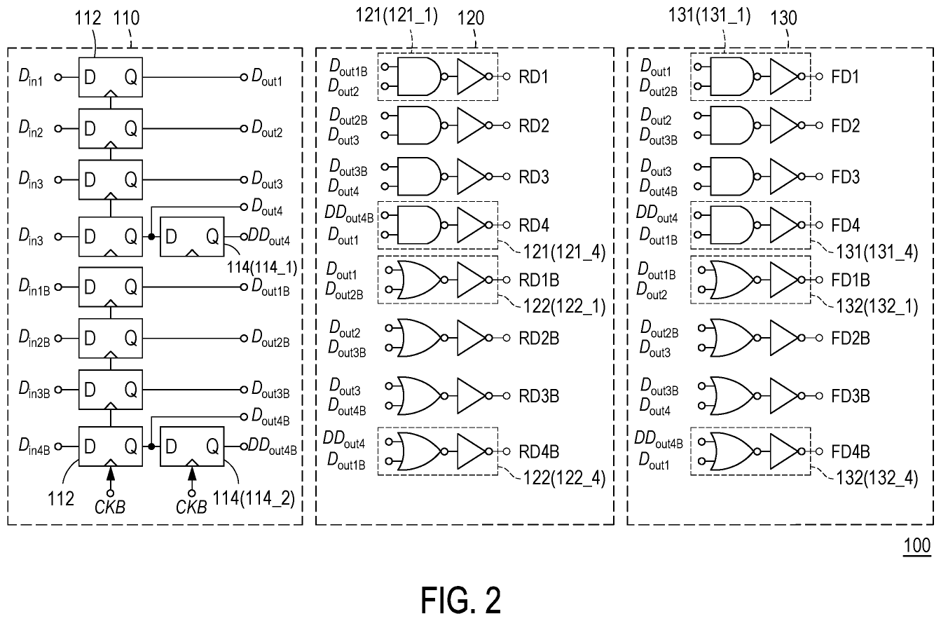

FIG. 2 is a circuit diagram showing an edge detector according to an embodiment of the disclosure. With reference to FIG. 2, the alignment circuit 110 is configured to align the received differential input data. The differential input data received by the alignment circuit 110 includes four sets of data (i.e., N is equal to 4), respectively Din1 and Din1B being a first set of differential input data. Din2 and Din2B being a second set of differential input data, Din3 and Din3B being a third set of differential input data, and Din4 and Din4B being a fourth set of differential input data.

Comparatively, the differential output data output by the alignment circuit 110 includes five sets of data (i.e., N+1 is equal to 5) respectively Dout1 and Dout1B being a first set of differential output data, Dout2 and Dout2B being a second set of differential output data, Dout3 and Dout3B being a third set of differential output data, Dout4 and Dout4B being a fourth set of differential output data, and DDout4 and DDout4B being a set of delayed differential output data.

Specifically, the alignment circuit 110 includes a plurality of flip-flops 112 and a plurality of latches 114. The coupling relationships between the flip-flops 112 and the latches 114 are shown in FIG. 2. For example, the flip-flop 112 is a D flip-flop having an input terminal D, an output terminal Q, and a clock input terminal. When a clock input CK transitions from 0 to 1, the output value is equal to the input value. The latches 114 receive an inverse clock CKB of the clock input CK to respectively delay the fourth set of differential output data Dout4 and Dout4B into the delayed differential output data DDout4 and DDout4B.

Then, the alignment circuit 110 outputs the differential output data Dout1, Dout1B, Dout2, Dout2B, Dout3, Dout3B, Dout4, Dout4B, DDout4, and DDout4B to the rising-edge detecting circuit 120 and the falling-edge detecting circuit 130 for detection.

The rising-edge detecting circuit 120 includes a plurality of AND gates (first type logic gates) 121 and a plurality of OR gates (second type logic gates) 122. In this embodiment, the AND gate is formed by combining one inverse AND gate and one inverter, and the OR gate is formed by combining one inverse OR gate and one inverter, but the disclosure is not limited thereto. In an embodiment, the AND gate may also be implemented by a single AND gate, and the OR gate may also be implemented by a single OR gate.

When the input data Din1 and Din2 of the alignment circuit 110 are respectively logic values 0 and 1, an AND gate 121_1 generates the rising data RD1 with a logic value of 1. As a result, the expected result can be obtained by taking the output data Dout1B and Dout2 of the alignment circuit 110 as the input data of the AND gate 121_1, where Dout1B and Dout2 are in-phase differential output data of different data sequences. Accordingly, the AND gate 121_1 generates the rising data RD1 with a logic value of 1. In other words, each of the first type logic gates 121 receives in-phase differential output data of different data sequences, and accordingly generates the corresponding rising data RD1, RD2, RD3, and RD4.

In addition, in terms of an AND gate 121_4, when the comparison data are input data Din4 and Din1, since the input data Din4 is to be compared with the next piece of input data Din1 instead of the current piece of input data Din1, a latch 114_1 may delay the input data Din4 by one bit, for example, to generate the delayed differential output data DDout4 and DDout4B. When the input data Din4 of the alignment circuit 110 and the next piece of input data Din1 are respectively logic values 0 and 1, the AND gate 121_4 (a first logic gate) generates the rising data RD4 with a logic value of 1. As a result, the expected result can be obtained by taking the output data DDout4B (a first differential data) and Dout1 of the alignment circuit 110 as the input data of the AND gate 121_4, where DDout4B and Dout1 are in-phase differential output data with DDout4B being delayed by a width of one bit. Accordingly, the AND gate 121_4 generates the rising data RD4 with a logic value of 1.

In addition, in the rising-edge detecting circuit 120, the OR gates 122 are used to generate differential data corresponding to outputs of the AND gates 121. For example, an OR gate 122_1 generates rising data RD1B according to the output data Dout1B and Dout2 of the alignment circuit 110. The rising data RD1B output by the OR gate 122_1 and the rising data RD1 output by the AND gate 121_1 form a set of differential rising data RD1 and RD1B. Similarly, an OR gate 122_4 (a second logic gate) receives the output data DDout4B and Dout1, and the output rising data RD4B and rising data RD4 form a set of differential rising data RD4 and RD4B. In other words, each of the second type logic gates 122 receives in-phase differential output data of different data sequences, and accordingly generates the corresponding rising data RD1B, RD2B. RD3B, and RD4B.

The falling-edge detecting circuit 130 includes a plurality of AND gates (third type logic gates) 131 and a plurality of OR gates (fourth type logic gates) 132. In this embodiment, the AND gate is formed by combining one inverse AND gate and one inverter, and the OR gate is formed by combining one inverse OR gate and one inverter, but the disclosure is not limited thereto. In an embodiment, the AND gate may also be implemented by a single AND gate, and the OR gate may also be implemented by a single OR gate.

When the input data Din1 and Din2 of the alignment circuit 110 are respectively logic values 1 and 0, an AND gate 131_1 generates rising data FD1 with a logic value of 1. As a result, the expected result can be obtained by taking the output data Dout1B and Dout2 of the alignment circuit 110 as the input data of the AND gate 131_1, where Dout1B and Dout2 are in-phase differential output data of different data sequences. Accordingly, the AND gate 131_1 generates the rising data FD1 with a logic value of 1. In other words, each of the third type logic gates 131 receives in-phase differential output data of different data sequences, and accordingly generates the corresponding rising data FD1. FD2. FD3, and FD4.

In addition, in terms of an AND gate 131_4, when the comparison data are input data Din4 and Din1, since the input data Din4 is to be compared with the next piece of input data Din1 instead of the current piece of input data Din1, a latch 114_2 may delay the input data Din4 by one bit, for example, to generate the delayed differential output data DDout4 and DDout4B. When the input data Din4 of the alignment circuit 110 and the next piece of input data Din1 are respectively logic values 1 and 0, the AND gate 131_4 (a third logic gate) generates the rising data FD4 with a logic value of 1. As a result, the expected result can be obtained by taking the output data DDout4 (second differential data) and Dout1 of the alignment circuit 110 as the input data of the AND gate 131_4, where DDout4 and Dout1B are in-phase differential output data with DDout4 being delayed by a width of one bit. Accordingly, the AND gate 131_4 generates the rising data FD4 with a logic value of 1.

In addition, in the falling-edge detecting circuit 130, the OR gates 132 are used to generate differential data corresponding to outputs of the AND gates 131. For example, an OR gate 132_1 generates the rising data FD1B according to the output data Dout1 and Dout2B of the alignment circuit 110. The rising data FD1B output by the OR gate 132_1 and the rising data FD1 output by the AND gate 131_1 form a set of differential rising data FD1 and FD1B. Similarly, an OR gate 132_4 (a fourth logic gate) receives the output data DDout4 and Dout1B, and the output rising data FD4B and rising data FD4 form a set of differential rising data FD4 and FD4B. In other words, each of the fourth type logic gates 132 receives in-phase differential output data of different data sequences, and accordingly generates the corresponding rising data FD1B, FD2B, FD3B, and FD4B.

Table 1 below is a truth table of the outputs and the inputs of the AND gates 121 and the AND gates 131:

TABLE 1

| A1b | A1 | B1 | RD | A2 | B2 | B2b | FD |
|---|---|---|---|---|---|---|---|
| 1 | 0 | 0 | 0 | 0 | 0 | 1 | 0 |
| 1 | 0 | 1 | 1 | 0 | 1 | 0 | 0 |
| 0 | 1 | 0 | 0 | 1 | 0 | 1 | 1 |
| 0 | 1 | 1 | 0 | 1 | 1 | 0 | 0 |

A1b and B1 are data input into the AND gates 121, and A1b is inverse data of A1; A2 and B2b are data input into the AND gates 131, and B2b is inverse data of B2.

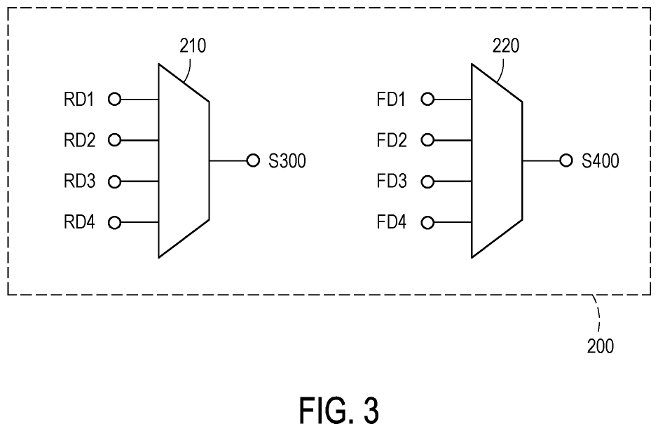

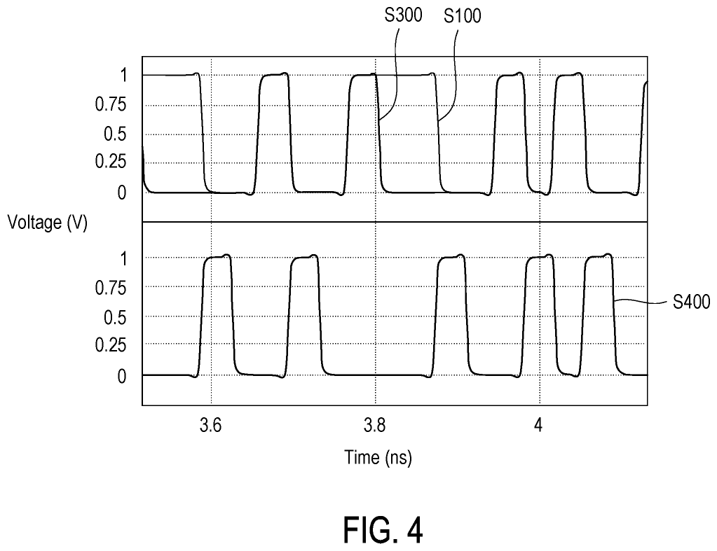

FIG. 3 is a schematic diagram showing a multiplexer circuit according to an embodiment of the disclosure. FIG. 4 is a schematic diagram showing full-rate pulse sequences according to an embodiment of the disclosure. With reference to FIG. 3 and FIG. 4, in this embodiment, the differential rising data RD1. RD2, RD3, and RD4 and the differential falling data FD1, FD2, FD3, and FD4 form full-rate pulse sequences S300 and S400 through a multiplexer circuit 200.

Specifically, the multiplexer circuit 200 includes a first multiplexer 210 and a second multiplexer 220. The first multiplexer 210 is a 4:1 multiplexer, for example. After receiving and serializing the differential rising data RD1, RD2, RD3, and RD4, the first multiplexer 210 outputs the full-rate pulse sequence S300, of which the waveform is as shown in FIG. 4. The second multiplexer 220 is a 4:1 multiplexer, for example. After receiving and serializing the differential falling data FD1, FD2, FD3, and FD4, the second multiplexer 220 outputs the full-rate pulse sequence S400, of which the waveform is as shown in FIG. 4. In FIG. 4, S100 is input data.

In summary of the foregoing, in the embodiments of the disclosure, the overall circuit of the rising-edge detecting circuit and the falling-edge detecting circuit has a total of 8 sets of AND gates and 8 sets of OR gates. Among them, 4 sets of AND gates and 4 sets of OR gates are used to generate a quarter-rate rising-edge pulse differential signal, and the other 4 sets of AND gates and 4 sets of OR gates are used to generate a quarter-rate falling-edge pulse differential signal. In addition, a level of latch is added to the last data path to delay the data. Through this edge detector architecture, burden of the logic gate may be eased, for example, the speed of the logic gate may be reduced, the bandwidth may be increased, and the operating speed of the VCSEL may be increased.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. An edge detector applied to a vertical-cavity surface-emitting laser, the edge detector comprising:
an alignment circuit configured to receive a plurality of sets of differential input data, and align the plurality of sets of differential input data to output a plurality of sets of corresponding differential output data, wherein the plurality of sets of differential output data comprise a set of delayed differential output data;
a rising-edge detecting circuit coupled to the alignment circuit, the rising-edge detecting circuit configured to detect rising edges of the plurality of sets of differential output data to output a plurality of sets of corresponding differential rising data; and
a falling-edge detecting circuit coupled to the alignment circuit, the falling-edge detecting circuit configured to detect falling edges of the plurality of sets of differential output data to output a plurality of sets of corresponding differential falling data.

2. The edge detector according to claim 1, wherein the alignment circuit receives N sets of differential input data and outputs N+1 sets of differential output data, and the edge detector is a one-Nth-rate edge detector.

3. The edge detector according to claim 2, wherein the alignment circuit receives four sets of differential input data, the edge detector is a quarter-rate edge detector, and an operating speed of the edge detector is 5 gigabit per second.

4. The edge detector according to claim 1, wherein the rising-edge detecting circuit comprises a plurality of first type logic gates and a plurality of second type logic gates, and each of the first type logic gates and the second type logic gates receives differential output data of a same timing.

5. The edge detector according to claim 4, wherein each of the first type logic gates and the second type logic gates receives in-phase differential output data of different data sequences.

6. The edge detector according to claim 4, wherein a first logic gate among the first type logic gates receives first differential data in the set of delayed differential output data, and a second logic gate among the second type logic gates receives the first differential data in the set of delayed differential output data.

7. The edge detector according to claim 6, wherein the falling-edge detecting circuit comprises a plurality of third type logic gates and a plurality of fourth type logic gates, and each of the third type logic gates and the fourth type logic gates receives differential output data of a same timing, wherein the first type logic gates and the third type logic gates are logic gates of the same type, and the second type logic gates and the fourth type logic gates are logic gates of the same type.

8. The edge detector according to claim 7, wherein each of the third type logic gates and the fourth type logic gates receives in-phase differential output data of different data sequences.

9. The edge detector according to claim 7, wherein a third logic gate among the third type logic gates receives second differential data in the set of delayed differential output data, and a fourth logic gate among the third type logic gates receives the second differential data in the set of delayed differential output data.

10. The edge detector according to claim 9, wherein the plurality of sets of differential rising data and the plurality of sets of differential falling data form a full-rate pulse sequence through a multiplexer circuit.
